(19) United States
(12) Patent Application Publication
(10) Pub. No.: US 2012/0125411 A1
(43) Pub. Date: May 24, 2012

(54) PARTIALLY TRANSPARENT FLEXIBLE THIN FILM SOLAR CELLS AND METHOD FOR THE PRODUCTION THEREOF

(75) Inventors: Steffen Ragnow, Leipzig (DE); Alexander Braun, Markkleeberg (DE); Karsten Otte, Leipzig (DE)

(73) Assignee: SOLARION AG PHOTOVOLTAIK, Leipzig (DE)

(21) Appl. No.: 13/321,890

(22) PCT Filed: May 24, 2010
(86) PCT No.: PCT/EP2010/003159

§ 371 Date: Feb. 8, 2012

(30) Foreign Application Priority Data
May 23, 2009 (DE) 10 2009 022 378.9

(51) Int. Cl. H01L 31/02; H01L 31/18

(52) U.S. Cl. 136/252; 438/73; 257/E31.113

(57) ABSTRACT

The disclosure provides transparent and partially transparent flexible thin film solar cells. The aim is achieved in that flexible thin film solar cells are processed using a tool, such that the entire cell structure is pierced, the transparency is ensured by the openings thus created, and the energy conversion yield remains high.

### CROSS-REFERENCE TO RELATED APPLICATIONS

This application is a United States National Stage of International Application No. PCT/EP2010/003159 filed on May 24, 2010. This application claims the benefit and priority of German Patent Application No. 10 2009 022 378.9, filed on May 23, 2009. The entire disclosures of the above applications are incorporated herein by reference.

### FIELD

The invention relates to a method of producing partially transparent flexible thin film solar cells that can be used in architecture as well as in the automobile industry.

### BACKGROUND AND SUMMARY

The production of thin film solar cells is already known. To this end thin film solar cells are interconnected on a solid carrier, usually glass, and etched with laser beams. An opening is created through which light can pass, thus producing the transparency. This functions in a natural manner only in transparent carriers, in particular in the case of glass as carrier. In addition, the use of an expensive production technology such as, e.g., laser technology, is necessary for producing the crossing points.

It is furthermore known that crystalline silicon wafers can be milled in such a manner that a cross grid is produced. The cross points are characterized by a total removal of material, so that a transparency is produced here that is desired.

The production of partially transparent thin film solar cells on flexible carrier material was not known up to now.

The invention has the goal of making available transparent or partially transparent thin film solar cells in an economically justifiable manner. This should be achieved by an intelligent course of the production method. The thin film solar cells in accordance with the invention should have a balanced ratio of optical transparency and electrical performance in order to do justice to the particular specific requirements of the area of use.

The invention has the task of indicating a method for the production of transparent or partially transparent thin film solar cells on a flexible carrier and of producing transparent or partially transparent thin film solar cells in accordance with this method.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1 shows a schematic plan view of a partially transparent thin film solar cell according to the present disclosure.

### DETAILED DESCRIPTION

The task is solved in that first a flexible thin film solar cell is produced in a known manner by a layered construction on a flexible carrier. The flexible carrier can be a plastic such as polyimide, metal foil, thin ceramic material, textile or the like. The layered construction of the thin film solar cell can result in CuInSe₂ (CIS), Cu(In,Ga)Se₂ (CIGS), Cu(In,Ga)(Se,S)₂ (CIGSS), or CuGaSe₂ (CGS) or in comparable thin film solar cells.

According to the invention, flexible thin film solar cells can be processed with a tool in such a manner that the entire cell construction including the flexible carrier is pierced. For example, a punching tool that produces openings as a pattern through the cell is suitable for this. The openings ensure the transparency and they act as a window for the light whereas the framework of the thin film solar cells ensures their stability.

Especially suitable tools are rotary punching tools but also microborers or laser beam arrangements.

The ratio of the areas between removed and remaining thin film solar cell is 5:1 to 1:60. A ratio of 1:8 is preferred. This ensures stability as well as transparency and limits the loss of energy conversion capacity.

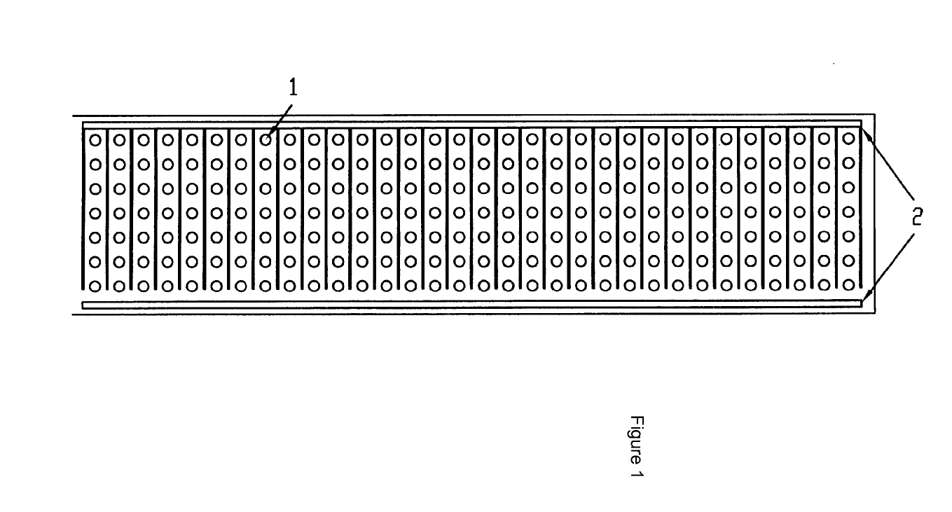

The discussed areal conditions are shown in FIG. 1.

In an embodiment of the invention the punched thin film solar cells are laminated in between transparent, rigid plates or foils so that a rigid and/or flexible stability is ensured that can be required in a number of application instances.

Extensive tests determined which punching patterns are especially suitable for securing the stability of the flexible thin film solar cell, ensuring the transparency to the desired extent and holding the energy yield at the required level.

The invention will be explained in detail in the following exemplary embodiments.

### Example 1

This example is not inventive and describes the production process of a CIGS thin film solar cell that is subsequently shaped in a partially transparent manner. The following process is used:

(a) Depositing of a layer of molybdenum on the entire surface of a polyimide foil in a known manner by DE sputtering.

(b) Depositing of the photoactive semiconductor layer (Cu(In,Ga)Se₂) on the entire surface by vacuum co-evaporation of the elements copper (Cu), indium (In), gallium (Ga) and selenium (Se).

(c) Depositing of a buffer layer on the entire surface, which layer preferably consists of cadmium sulfide (CdS) in a wet chemical bath, e.g., according to DE 10 2007 036 715.

(d) Depositing of an intrinsic zinc oxide layer (i-ZnO) on the entire surface by RF sputtering.

(e) Depositing of an aluminum-doped zinc oxide layer (ZnO:Al) on the entire surface by DC sputtering.

(f) Production of structuring grooves by mechanical scratching.

(g) Application of the contact fingers and collector contactors by printing with polymer paste containing electrically conductive particles in the screen printing method and subsequent drying of the printed paste.

(h) Individualization of the solar cells to appropriate dimensions by means of a rotary punch.

The following variants were realized in further examples:

Re (a): In addition to polyimide foil other temperature-stable polymer foils, metal foils glass substrates or composite materials (e.g., glass-fiber-reinforced textiles) were used as substrates. The molybdenum layer can also consist of several metal layers.

Re (b): in addition to Cu(In,Ga)Se₂, the compounds CuGaSe₂, CuInSe₂, CuGaS₂, CuInS₂, Cu(In,Ga)(S,Se)₂ were also used as photoactive layer. The photoactive layer can also be produced by a printing process, a galvanic depositing or by sputtering on the metals and Cu, In, Ga and subsequent seleniumization.

Re (c): The CdS layer was replaced by alternative buffers such as, e.g., ZnS, ZnSe, InS, InSe, ZnMgO, etc.

Re (e): ZnO:Al was replaced, e.g., by ZnO:Ga, ZnO:B or ITO.

Re (f): The production of the structuring grooves took place with the aid of lasers.

Re (g): The contact fingers and collector contacts were deposited by vacuum evaporation of the metal and the using of shadow masks.

Re (h): The individualization of the solar cells took place with lasers or mechanical punching such as, e.g., flat bed punching.

### Example 2

The method for the production of partially transparent thin film solar cells starts from thin film solar cells that are capable of functioning and treats them as follows.

After the processing step g) (application of the contact grid) the individualization of the cells in the required magnitudes takes place by means of a rotary punch. At the same time, areas between the contact fingers are punched out with the same rotary punch in order to achieve a partial transparency.

The punched-out areas can have any desired forms such as, e.g., rectangles, squares, stars, crosses, etc. (with or without rounded-off corners) in addition to the patterns shown in the figures. Circles are preferred forms. In the case of circles there is the least risk of tearing in and thus damaging the flexible thin film solar cell.

During the stamping the entire layered construction of the solar cell including the flexible substrate is pierced.

As an alternative to rotary punches, any desired mechanical punches such as, e.g., flat-bed punches, microborers or lasers can be used.

The thin film solar cell used in the example stems from the production of the Solarion AG Leipzig and has the following parameters before the punching:

Total area=3906 mm2

Transparency=0%

Power=250 mW

The flexible thin film solar cell will now be worked.

A rotary punch is used as punching tool. After the treatment has taken place the cells have the following parameters.

| Example cell 1 | Example cell 2 |
|---|---|
| Total area = 3472 mm2 | Total area = 3584 mm2 |
| Transparency = 11% | Transparency = 9% |
| Power = 220 mW | Power = 212 mW. |

The punching-out can also take place in accordance with the invention prior to the application of the contact fingers (process step g) or prior to the generation of the structuring grooves (process step f).

### Example 3

The flexible thin film solar cells are fixed and contacted between two transparent, rigid bearing areas, namely, glass plates.

Alternatively, the thin film solar cells are fixed and contacted between two transparent, flexible bearing areas, namely, plastic foils.

1. A method for the production of partially transparent thin film solar cells, characterized in that flexible thin film solar cells are worked with a tool in such a manner that they, as well as a carrier foil, are pierced in a pattern, whereby the pattern ensures the mechanical stability of the flexible thin film solar cell as well as the degree of efficiency of the conversion of energy and the optical transparency striven for.

2. The method according to claim 1, wherein the ratio between removed and remaining areas of flexible thin film solar cells is between 5:1 and 1:60.

3. The method according to claim 2, wherein the ratio is 1:8.

4. The method according to claim 1, wherein a pattern consists of regularly arranged, circular punched-out areas.

5. The method according to claim 1, wherein the punched-out areas represent rectangles, including squares or stars or crosses.

6. The method according to claim 1, wherein in order to bring the openings into the flexible thin film solar cells punches, microborer arrangements or laser beam arrangements are used.

7. The method according to claim 1, wherein the partially transparent, flexible thin film solar cells are interconnected to modules.

8. The method according to claim 1, wherein the flexible, partially transparent thin film solar cells are fixed between rigid, transparent carriers.

9. The method according to claim 1, wherein the flexible, partially transparent thin film solar cells are fixed between flexible, transparent carriers.

10. A partially transparent, flexible thin film solar cell, characterized in that the carrier foil including the energy-converting layers carry openings that make possible the passage of light and ensure the partial transparency.
